(19) United States
(12) Patent Application Publication
(10) Pub. No.: US 2026/0059823 A1
(43) Pub. Date: Feb. 26, 2026

(54) Formation of Silicon Carbide Semiconductor Contact Structures

(71) Applicant: X-FAB Texas, Inc., Lubbock, TX (US)

(72) Inventors: Tyler Tucker, Lubbock, TX (US); Jeff Smith, Shallowater, TX (US)

(21) Appl. No.: 18/813,319

(22) Filed: Aug. 23, 2024

(51) Int. Cl. H01L 21/04; H01L 29/16; H01L 29/45

(52) U.S. Cl. CPC H01L 21/0485; H10D 62/8325; H10D 64/62; H01L 21/049

(57) ABSTRACT

A method of forming a contact structure for a silicon carbide semiconductor device, the method comprises the following steps in the following order:
forming a gate structure for a transistor comprising a source region in a semiconductor layer;
forming a silicide layer on the source region, wherein the silicide layer is self-aligned with the gate structure;
providing a dielectric layer over the silicide layer;
patterning the dielectric layer to form an opening to the silicide layer; and
providing a metal in the opening to form an electric contact to the source region.

### TECHNICAL FIELD

The invention concerns the formation of silicon carbide (SiC) contact structures.

### BACKGROUND

Silicon carbide technology is seeing increasing interest as an alternative to conventional silicon technology for specific application areas. However, due to the unique properties of this material, conventional semiconductor processing developed for silicon technology may not be directly usable. Therefore, new methods and processes for forming SiC devices are required.

Currently in SiC processing the contacts and “vias” to the top “power” metal are formed by depositing and reflowing an interlayer dielectric (ILD), depositing Nickel and forming NiSi contacts, and then finally depositing the power metal. A similar process is described in, US20200365708A1, which uses a reflowed dielectric. However, these processes can put limitations on the dimensions of SiC devices, which, as the technology shrinks, will become a problem in future.

### SUMMARY

Aspects of the present invention provide a contact structure for a SiC device and methods of forming such, as set out in the appended claims.

Specific embodiments will now be described with reference to the accompanying drawings.

### BRIEF DESCRIPTION OF DRAWINGS

FIG. 1 shows a schematic cross section of a part of a SiC wafer; and

FIGS. 2A to 2G show subsequent schematic cross sections of a part of a SiC wafer during contact formation.

### DETAILED DESCRIPTION

To at least partly overcome the existing problems of SiC contact formation for a source contact of a SiC transistor, it is proposed to form a gate aligned silicide on the source region of a SiC transistor before providing an ILD and forming the metal via (also referred to as “metal plug”). To shrink cell pitches, reduce reliance of lithography processes, and improve device performance of SiC devices, the silicide needs to be formed before the ILD is deposited.

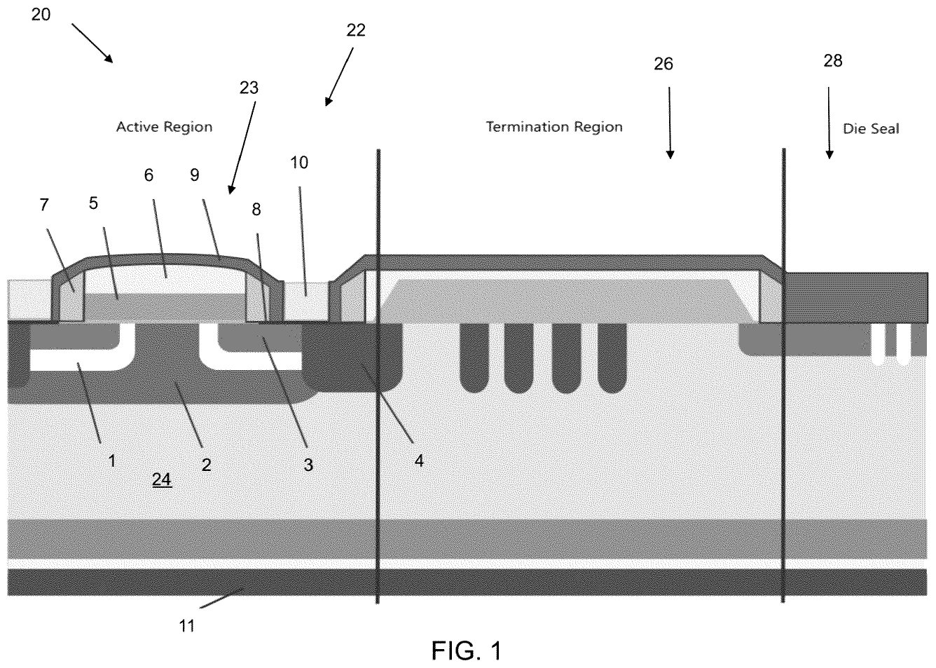

FIG. 1 shows a schematic cross section of a part of SiC wafer/die 20 comprising a semiconductor structure 22 comprising a vertical transistor. The semiconductor structure 22 comprises PWell region 1, a JFET region 2, an NPlus (n+) region 3 (also referred to as the source region), a PPlus (p+) region 4, a gate structure 23 comprising a conductive gate layer 5 (typically doped polysilicon) on the gate oxide (GOX), and an insulating gate layer 6 as well as oxide gate spacers 7. On the NPlus region 3 there is located an ohmic contact 8 (e.g. a NiSi silicide layer), connected to a metal via 10 through the inter layer dielectric (ILD) layer 9. The metal via 10 (typically tungsten) provides the electrical connection between the source region 3 and the power metal (not shown). On the other side of the substrate 24, a drain contact 11 is located. In use, when the transistor is on, current flows from the source region 3 through the substrate 24 and to the drain contact 11.

FIG. 1 further shows a termination region 26 of the wafer 20 and a die seal 28 of the wafer 20, located at the edge of the wafer 20. Typically, a plurality of SiC devices (such as the illustrated transistor) may be located adjacent to each other between termination regions 26. The termination region 26 may improve the electric fields at the edges of SiC devices, for example by including one or more doped rings that can help spread an electric field in the substrate 24.

To form a gate aligned silicide, multiple layers are provided before beginning the ILD process. To form silicide contacts before ILD deposition a layer of TEOS can be added to the gate poly stack. This oxide layer ensures that nickel will not contact poly during the rapid thermal process (RTP) step of silicidation. The Gate poly stack can be patterned and then go through an oxide etch and followed by the standard poly etch to form the so called gate runners.

To protect the gate poly sidewalls from nickel, another high uniformity TEOS layer can be deposited. This TEOS layer can vary in thickness but may be at least 1 kÅ thick to provide sufficient protection. The wafer then undergoes a sidewall oxide etch to clear the SiC surface for Nickel deposition and form oxide gate spacers of the gate structure.

Nickel can then be deposited and silicided to form a low resistance layer or ohmic contact on the semiconductor layer (over the source region).

Whilst gate aligned contacts are not new to silicon technology as such, it has not been previously considered for SiC processes where well and contact formation is not patterned by the gate. Until now there has not been a need to shrink contacts smaller than 1 μm on SiC, which has allowed the conventional SiC contact formation.

To successfully shrink vias and the cell pitch, it is preferential to use tungsten (W) deposition and etch back like that, which can help to provide vias smaller than 1.0 μm, while mitigating potential gate leakage. The W plug process can allow for better control of the ILD, better metal fill, and smaller cell pitches.

The tungsten plug process starts after the silicide formation with depositing the ILD (e.g. silicon oxide formed by TEOS and borophosphorous TEOS (BPTEOS), followed by densification). Then the openings in the ILD for the source vias are patterned and etched.

In conventional technology, after a source via etch, there is another process to reflow the ILD that gives it a sloped profile, but for the proposed tungsten plug process this is not used. Instead, tungsten and any barrier layers are deposited and etched back. This can provide a planar surface for the power metal to be deposited on. This process also gives the ability to make contact to both gate and source with 1 etch as the NiSi contacts have already been formed.

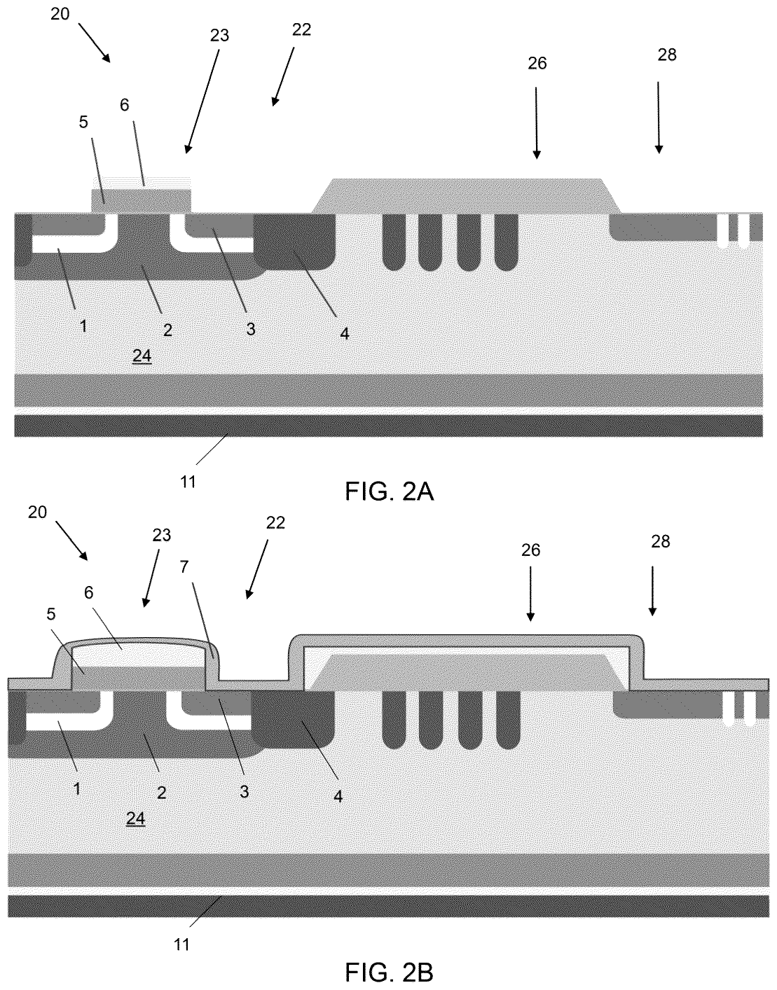

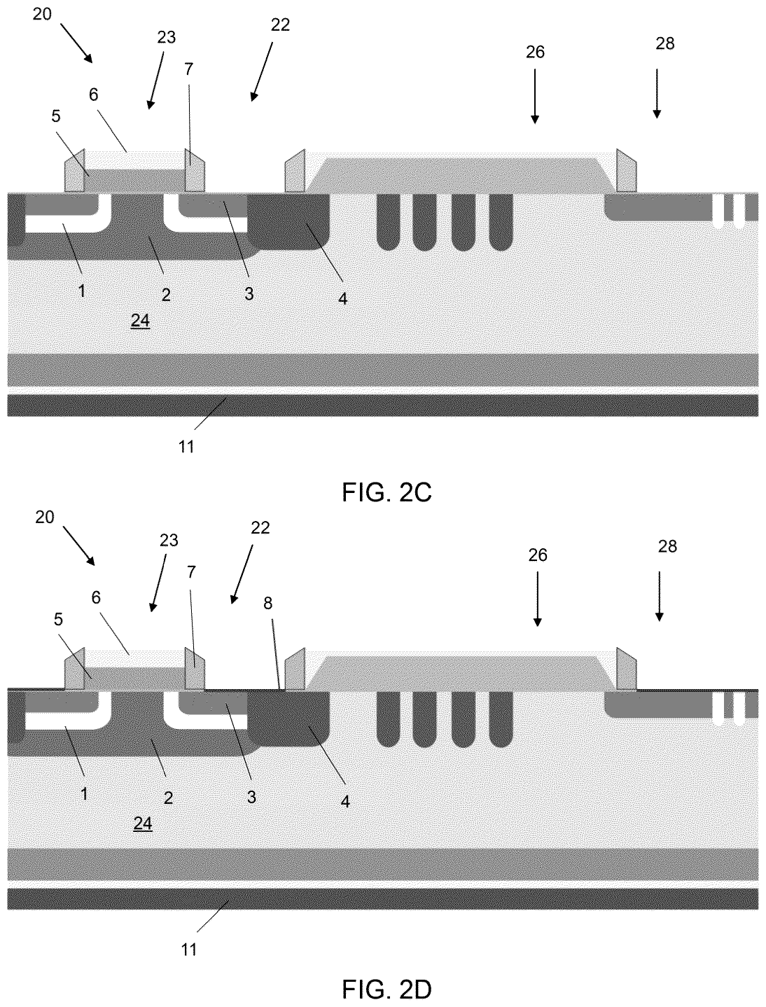

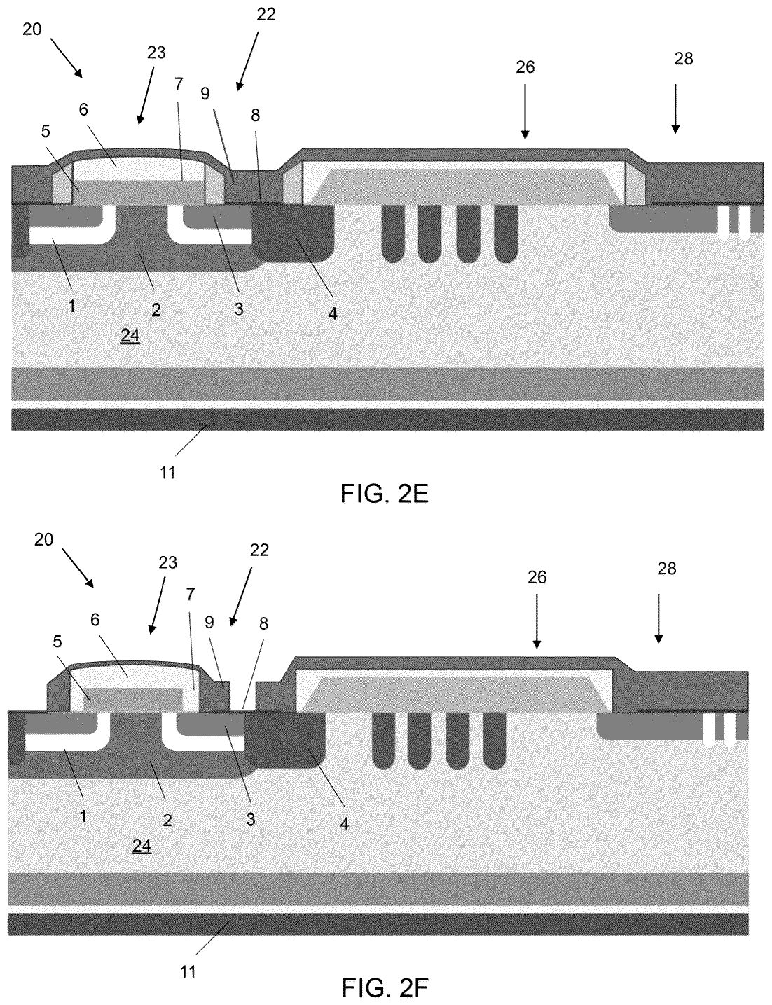

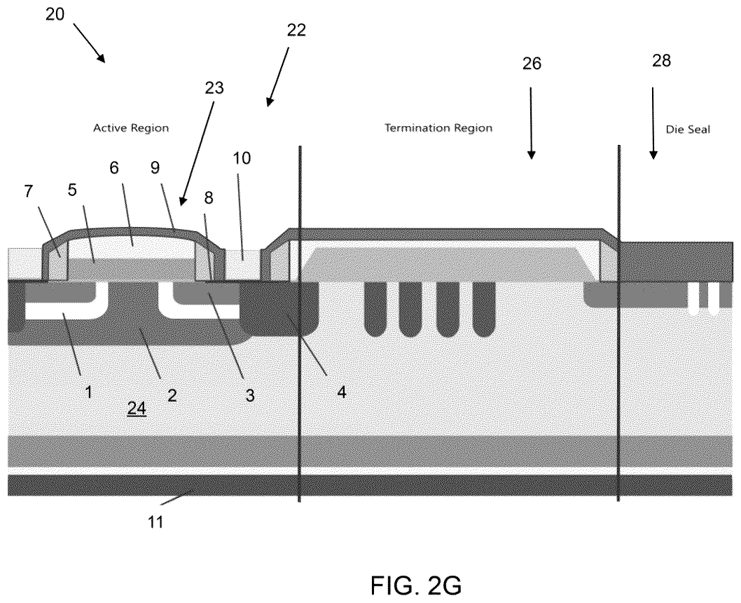

FIGS. 2A to 2G show sequential cross sections of a semiconductor structure 22 in the contact formation processes in order to provide the contact structure described in relation to FIG. 1 above. To aid understanding, the same reference numerals have been used for equivalent features in different figures.

In FIG. 2A, the gate structure 23 has been patterned and etched to form a gate runner comprising the gate oxide, the conductive gate layer 5 (e.g. poly) and the insulating gate layer 6 (e.g. silicon oxide).

In FIG. 2B, a dielectric layer for forming gate spacers 7 is blanket deposited over the gate structure and over the NPlus source region 3.

In FIG. 2C, the dielectric layer is patterned (comprising an etch step) to form gate spacers 7 and to expose the underlying NPlus source region 3.

In FIG. 2D, the ohmic contact 8 is formed on the NPlus region 3. The ohmic contact 8 is aligned to the gate structure 23, while the gate is protected by the gate spacers 7. The ohmic contact 8 may be formed by depositing Ni, thermally reacting the Ni with the underlying SiC material to form a silicide, and then removing any excess (unreacted) Ni.

In FIG. 2E, an ILD 9 is blanket deposited over the gate structure 23 and over the NPlus source region 3 (on top of the ohmic contact 8). The ILD 9 may comprise a combination of silicon oxide and a reflowable BPTEOS.

In FIG. 2F, the ILD 9 is patterned and etched to form openings over the NPlus source region 3 down to the ohmic contact 8.

In FIG. 2G, metal vias 10 are formed in the opening of the ILD 9 to contact the ohmic contacts 8 and thereby the source region 3. Forming the metal vias 10 may comprise depositing one or more barrier layers (not shown), depositing tungsten and then removing the tungsten on top of the ILD 9 by etching. The etchback to remove the excess tungsten typically stops on the barrier layers.

In general, embodiments described herein provide a method of forming a contact structure for a silicon carbide semiconductor device, the method comprising the following steps in the following order:
forming a gate structure for a transistor comprising a source region in a semiconductor layer;
forming a silicide layer on the source region, wherein the silicide layer is self-aligned with the gate structure;
providing a dielectric layer over the silicide layer;
patterning the dielectric layer to form an opening to the silicide layer; and
providing a metal in the opening to form an electric contact to the source region.

The step of forming the gate structure may comprise:
forming a gate oxide layer on the semiconductor layer;
depositing a polysilicon layer on the gate oxide layer;
doping the polysilicon layer with a dopant; and patterning the polysilicon layer and the gate oxide.

A layer of tungsten silicide (WSi) may also be deposited on the polysilicon layer followed by a silicon oxide.

Before patterning the polysilicon layer, the method may comprise depositing a Silicon oxide layer being tetraethoxysilane (TEOS) layer for protecting the gate structure.

Providing the dielectric layer may comprise blanket depositing a layer of silicon oxide over said source region and over said gate structure.

Forming a gate structure may further comprise, forming gate spacers, which may comprise depositing an oxide layer and etching the oxide layer to reveal the source region.

Forming the silicide layer may comprise:
depositing nickel on the source region;
heating nickel to cause silicide to form on the source region;
removing unreacted nickel; and annealing the silicide.

Patterning the dielectric layer typically comprises photolithography to form the opening with substantially vertical side walls. The opening may have a width that is less than or equal to 1 μm. This is substantially smaller than what existing technology for SiC can produce with sufficiently high quality. Preferably, the metal is tungsten, which can provide a better fill than copper.

The semiconductor layer can be formed on a first side of a semiconductor substrate and a drain region of the transistor can be located on a second and opposite side of the semiconductor substrate (a vertical transistor).

Embodiments described herein can further provide a silicon carbide device comprising a semiconductor structure formed as described above.

Embodiments may provide a silicon carbide device comprising:
gate structure for a transistor;
a semiconductor layer comprising a source region of a source of the transistor;
a silicide layer on the source region, wherein the silicide layer is self-aligned with the gate structure;
a dielectric layer over the silicide layer; and
a metal via through the dielectric layer and connected to the source region.

The metal via preferably comprises tungsten, and the via is preferably no wider than 1 μm.

The invention may be defined by any of the following numbered clauses.

1. A method of forming a contact structure for a silicon carbide semiconductor device, the method comprising the following steps in the following order:
forming a gate structure for a transistor comprising a source region in a semiconductor layer;
forming a silicide layer on the source region, wherein the silicide layer is self-aligned with the gate structure;
providing a dielectric layer over the silicide layer;
patterning the dielectric layer to form an opening to the silicide layer; and providing a metal in the opening to form an electric contact to the source region.

2. A method according to clause 1, wherein the step of forming the gate structure comprises:
forming a gate oxide layer on the semiconductor layer;
depositing a polysilicon layer on the gate oxide layer;
doping the polysilicon layer with a dopant; and
   patterning the polysilicon layer and the gate oxide.

3. A method according to clause 1 or 2, further comprising, before patterning the polysilicon layer, depositing a silicon oxide layer being tetraethoxysilane (TEOS) layer for protecting the gate structure.

4. A method according to any one of the preceding clauses, wherein providing the dielectric layer comprises blanket depositing a layer of silicon oxide over said source region and over said gate structure.

5. A method according to any one of the preceding clauses, wherein forming a gate structure further comprises forming gate spacers.

6. A method according to clause 5, wherein the step of forming the gate spacers comprises depositing an oxide layer and etching the oxide layer to reveal the source region.

7. A method according to any one of the preceding clauses, wherein forming the silicide layer comprises:
depositing nickel on the source region;
heating nickel to cause silicide to form on the source region;
removing unreacted nickel; and
annealing the silicide.

8. A method according to any one of the preceding clauses, wherein patterning the dielectric layer comprises photolithography to form the opening with substantially vertical side walls.

9. A method according to any one of the preceding clauses, wherein the opening has a width that is less than or equal to 1 μm.

10. A method according to any one of the preceding clauses, wherein said metal is tungsten.

11. A method according to any one of the preceding clauses, wherein the semiconductor layer is formed on a first side of a semiconductor substrate and a drain region of the transistor is located on a second and opposite side of the semiconductor substrate.

12. A silicon carbide device comprising a semiconductor structure formed according to any one of the preceding clauses.

13. A silicon carbide device comprising:
gate structure for a transistor;
a semiconductor layer comprising a source region of a source of the transistor;
   a silicide layer on the source region, wherein the silicide layer is self-aligned with the gate structure;
   a dielectric layer over the silicide layer; and
   a metal via through the dielectric layer and connected to the source region.

14. A silicon carbide device according to clause 13, wherein the metal via comprises tungsten.

15. A silicon carbide device according to clause 13 or 14, wherein the opening has a width that is less than or equal to 1 μm.

While specific embodiments of the invention have been described above, it will be appreciated that the invention may be practiced otherwise than as described. The descriptions above are intended to be illustrative, not limiting. It will be apparent to one skilled in the art that modifications may be made to the invention as described without departing from the scope of the claims set out below.

Each feature disclosed or illustrated in the present specification may be incorporated in the invention, whether alone or in any appropriate combination with any other feature disclosed or illustrated herein.

1. A method of forming a contact structure for a silicon carbide semiconductor device, the method comprising the following steps in the following order:
forming a gate structure for a transistor comprising a source region in a semiconductor layer;
forming a silicide layer on the source region, wherein the silicide layer is self-aligned with the gate structure;
providing a dielectric layer over the silicide layer;
patterning the dielectric layer to form an opening to the silicide layer; and
providing a metal in the opening to form an electric contact to the source region.

2. A method according to claim 1, wherein the step of forming the gate structure comprises:
forming a gate oxide layer on the semiconductor layer;
depositing a polysilicon layer on the gate oxide layer;
doping the polysilicon layer with a dopant; and
patterning the polysilicon layer and the gate oxide.

3. A method according to claim 1, further comprising, before patterning the polysilicon layer, depositing a silicon oxide layer being tetraethoxysilane (TEOS) layer for protecting the gate structure.

4. A method according to claim 1, wherein providing the dielectric layer comprises blanket depositing a layer of silicon oxide over said source region and over said gate structure.

5. A method according to claim 1, wherein forming a gate structure further comprises forming gate spacers.

6. A method according to claim 5, wherein the step of forming the gate spacers comprises depositing an oxide layer and etching the oxide layer to reveal the source region.

7. A method according to claim 1, wherein forming the silicide layer comprises:
depositing nickel on the source region;
heating nickel to cause silicide to form on the source region;
removing unreacted nickel; and
annealing the silicide.

8. A method according to claim 1, wherein patterning the dielectric layer comprises photolithography to form the opening with substantially vertical side walls.

9. A method according to claim 1, wherein the opening has a width that is less than or equal to 1 μm.

10. A method according to claim 1, wherein said metal is tungsten.

11. A method according to claim 1, wherein the semiconductor layer is formed on a first side of a semiconductor substrate and a drain region of the transistor is located on a second and opposite side of the semiconductor substrate.

12. A silicon carbide device comprising a semiconductor structure formed according to claim 1.

13. A silicon carbide device comprising:
gate structure for a transistor;
a semiconductor layer comprising a source region of a source of the transistor;
a silicide layer on the source region, wherein the silicide layer is self-aligned with the gate structure;
a dielectric layer over the silicide layer; and
a metal via through the dielectric layer and connected to the source region.

14. A silicon carbide device according to claim 13, wherein the metal via comprises tungsten.

15. A silicon carbide device according to claim 13, wherein the opening has a width that is less than or equal to 1 μm.
